(19) United States
(12) Patent Application Publication
(10) Pub. No.: US 2024/0376345 A1
(43) Pub. Date: Nov. 14, 2024

(54) ADHESIVE SHEET AND FLEXIBLE IMAGE DISPLAY DEVICE

(71) Applicant: MITSUBISHI CHEMICAL CORPORATION, Tokyo (JP)

(72) Inventor: Kazunobu TADA, Tokyo (JP)

(73) Assignee: MITSUBISHI CHEMICAL CORPORATION, Tokyo (JP)

(21) Appl. No.: 18/780,330

(22) Filed: Jul. 22, 2024

Related U.S. Application Data
(63) Continuation of application No. PCT/JP2023/008709, filed on Mar. 8, 2023.

(30) Foreign Application Priority Data
Mar. 14, 2022 (JP) 2022-039243

(51) Int. Cl. C09J 7/30; C09J 4/06; C09J 133/08; H10K 59/80; H10K 102/00

(52) U.S. Cl. CPC C09J 7/30; C09J 4/06; C09J 133/08; C09J 2433/00; H10K 59/873; H10K 2102/311

(57) ABSTRACT

Provided is an adhesive sheet having good flexibility and recovering ability, and excellent adhesiveness. An adhesive sheet having a storage shearing elastic modulus at −20° C. [G′(−20° C.)] of not greater than 700 kPa, wherein the adhesive sheet is formed from an adhesive composition [I] including an acrylic polymer (A) and a radically polymerizable compound (B), the acrylic polymer (A) includes: a structural portion derived from an alkyl (meth)acrylate (a1) with an alkyl group having 5 to 20 carbon atoms; and a structural portion derived from a hydroxy-group-containing (meth)acrylate (a2), and the radically polymerizable compound (B) includes a di(meth)acrylate (B1) having an alkylene group having 2 to 4 carbon atoms.

### RELATED APPLICATIONS

This application is a continuation of International Application No. PCT/JP2023/008709, filed on Mar. 8, 2023, which claims priority to Japanese Patent Application No. JP 2022-039243, filed on Mar. 14, 2022, the entire contents of each of which are herein incorporated by reference.

### TECHNICAL FIELD

The present disclosure relates to an adhesive sheet, specifically an adhesive sheet suitably usable for laminating a constituent member of an image display device composed of curves and a foldable and flexible image display device, and a flexible image display device using this adhesive sheet.

### BACKGROUND ART

In recent years, image display devices composed of curves and foldable and flexible image display devices that use an organic light-emitting diode (OLED) and a quantum dot (QD) have been developed and commercially used widely.

Such image display devices have laminate structures in which a plurality of member sheets such as a cover lens, a circularly polarizing plate, a touch film sensor, and a light-emitting element are laminated with a transparent adhesive sheet, and each of the laminate structures can be regarded as a laminated sheet in which the member sheet and the adhesive sheet are laminated.

The foldable and flexible image display device has various problems caused by interlayer stress when folded. For example, the layers may be peeled therebetween when folded (delamination: a phenomenon of peeling between the layers is called as “delamination”) and a laminated sheet that is not peeled even when folded is required.

In addition, a laminated sheet is required in which an effect by placing in a bent state does not remain and in which the state is rapidly recovered to a flat state when the display is opened from a folded state.

Furthermore, repeating the folding operations applies stress to the member sheets being adherends of the adhesive sheet to cause cracking, finally leading to breakage. In particular, a laminated sheet durable for repeating folding operations at low temperature, which is a severer condition, is also required.

As for the foldable and flexible image display device, PTL 1, for example, discloses: an adhesive composition for a foldable display comprising a thermosetting resin and a crosslinker, wherein the thermosetting resin has a unit derived from a compound containing at least one of N or O and at least one unshared electron pair in a molecule, and the thermosetting resin has a glass transition temperature of not higher than −70° C.; an adhesive film using the same; and a foldable display comprising the same. Specifically, disclosed are: an adhesive composition for a foldable display containing a composition in which an epoxy-based crosslinker or an isocyanate-based crosslinker is blended with a thermosetting resin in which carbitol acrylate, ethylhexyl acrylate, and acrylic acid are copolymerized; an adhesive film using the same; and a foldable display comprising the same.

PTLs 2 and 3 focus on strain with applying a shearing force and a restoring force, and disclose an adhesive aiming to improve durability and step-following ability.

### RELATED ART DOCUMENT

### Patent Document

PTL 1: JP-A-2021-500445
PTL 2: JP-A-2020-196903
PTL 3: JP-A-2020-143284

### SUMMARY OF THE DISCLOSURE

### Problem to be Solved by the Disclosure

However, although the adhesive film disclosed in PTL 1 containing much carbitol acrylate has a small storage elastic modulus at low temperature and thereby can reduce the stress due to the folding, meanwhile the adhesiveness is low, and the above adhesive film has a problem of delamination that easily occurs with the member sheet when folded specifically under a low-temperature state. In addition, the carbitol acrylate easily relaxes the internal stress due to an internal rotation around the ether bond, and thereby the above adhesive film has a problem of a folding trace not rapidly disappearing when the folding operation is performed.

PTLs 2 and 3 aim to improve durability and step-following ability, but are not about the adhesive sheet used for laminating the constituent member of the flexible image display device. PTLs 2 and 3 do not consider the specific problems such that the delamination and the folding trace remain derived from a high elastic modulus with folding operation, specifically under a low temperature environment, and do not solve these problems.

The present disclosure relates to an adhesive sheet having a storage shearing elastic modulus at low temperature and formed from an adhesive composition containing an acrylic polymer. The present disclosure provides: an adhesive sheet used for laminating a constituent member of a flexible image display device that has recovering ability of recovering to a flat state when the folding operation is performed (also referred to as “strain recovering ability”) and that has improved adhesiveness not causing delamination with folding; and a flexible image display device using the same.

### Means for Solving the Problems

Accordingly, the present inventors have made earnest study in view of the above circumstances, and consequently found that good flexibility and recovering ability are exhibited and the adhesiveness can be improved by using an adhesive sheet having a storage shearing elastic modulus at −20° C. [G′(−20° C.)] of not greater than a predetermined value, wherein the adhesive sheet is formed from an adhesive composition containing an acrylic polymer and a radically polymerizable compound, the acrylic polymer having a relatively long-chain alkyl group and a hydroxy group, and a di(meth)acrylate having a relatively short-chain alkylene group in combination.

Specifically, the present disclosure has the following aspects.

[i] An adhesive sheet having a storage shearing elastic modulus at −20° C. [G′(−20° C.)] of not greater than 700 kPa, wherein
the adhesive sheet is formed from an adhesive composition [I] comprising an acrylic polymer (A) and a radically polymerizable compound (B),
the acrylic polymer (A) comprises: a structural portion derived from an alkyl (meth)acrylate (a1) with alkyl group having 5 to 20 carbon atoms; and a structural portion derived from a hydroxy-group-containing (meth)acrylate (a2), and
the radically polymerizable compound (B) comprises a di(meth)acrylate (B1) having an alkylene group having 2 to 4 carbon atoms.

[ii] The adhesive sheet according to [i], wherein the storage shearing elastic modulus at −20° C. [G′(−20° C.)] is not greater than 500 kPa.

[iii] The adhesive sheet according to [i] or [ii], wherein the alkyl (meth)acrylate (a1) is a linear alkyl (meth)acrylate.

[iv] The adhesive sheet according to any of [i] to [iii], wherein the acrylic polymer (A) has a weight-average molecular weight of 600,000 to 1,500,000.

[v] The adhesive sheet according to any of [i] to [iv], wherein the acrylic polymer (A) has a glass transition temperature (Tg) of not lower than −50° C. and not higher than −10° C., the Tg being obtained by a dynamic viscoelasticity measurement with a shearing mode at a frequency of 1 Hz and being defined by a maximum point of a loss tangent (tan δ).

[vi] The adhesive sheet according to any of [i] to [iv], wherein the acrylic polymer (A) has a glass transition temperature (Tg) of not lower than −50° C. and lower than −25° C., the Tg being obtained by a dynamic viscoelasticity measurement with a shearing mode at a frequency of 1 Hz and being defined by a maximum point of a loss tangent (tan δ).

[vii] The adhesive sheet according to any of [i] to [vi], wherein the di(meth)acrylate (B1) is a di(meth)acrylate having a linear alkylene group.

[viii] The adhesive sheet according to any of [i] to [vii], wherein the radically polymerizable compound (B) is contained by 0.1 to 10 parts by mass relative to 100 parts by mass of the acrylic polymer (A).

[ix] The adhesive sheet according to any of [i] to [viii], wherein the adhesive sheet has a gel fraction of 30 to 95 mass %.

[x] The adhesive sheet according to any of [i] to [viii], wherein the adhesive sheet has a gel fraction of 30 to 65 mass %.

[xi] The adhesive sheet according to any of [i] to [x], wherein the adhesive sheet is used for laminating a constituent member of a flexible image display device.

[xii] A flexible image display device, comprising the adhesive sheet according to any of [i] to [xi].

### Effects of the Disclosure

The adhesive sheet of the present disclosure has a low storage shearing elastic modulus at low temperature, and is formed from an adhesive composition containing the specific alkyl-group-containing and hydroxy-group-containing acrylic polymer and the specific di(meth)acrylate. Therefore, the adhesive sheet has good flexibility and recovering ability and an improved adhesiveness, and can be suitably used particularly as the adhesive sheet used for the flexible image display device.

### EMBODIMENTS OF THE DISCLOSURE

Hereinafter, the present disclosure will be described in detail.

In the present disclosure, the term “film” is intended to encompass “sheet,” and the term “sheet” is intended to encompass “film.”

The term “panel” as used in “image display panel” and “protection panel” is intended to encompass plates, sheets, and films.

In the present disclosure, “X to Y,” wherein X and Y are given numbers, is intended to encompass “preferably greater than X” and “preferably less than Y” unless otherwise specified, in addition to a meaning of “not less than X and not greater than Y.”

The expression “not less than X,” wherein X is a given number, is intended to encompass “preferably greater than X” unless otherwise specified. The expression “not greater than Y,” wherein Y is a given number, is intended to encompass “preferably less than Y” unless otherwise specified.

Further, the expression “X and/or Y,” wherein X and Y are each a given form, is intended to mean at least one of X and Y, and to mean the following three meanings: only X; only Y; and X and Y.

In the present disclosure, “main component” means a component that significantly affects properties of an object, and a content of the component is typically not less than 30 mass %, preferably not less than 35 mass %, and more preferably not less than 50 mass % in the object. The main component is often a component with the highest mass proportion in the object, and cases are assumed where the proportion is not less than 50 mass %, specifically not less than 55 mass %, specifically not less than 60 mass %, specifically not less than 70 mass %, specifically not less than 80 mass %, and specifically not less than 90 mass % (including 100 mass %).

In the present disclosure, the term “(meth)acryl” means to encompass “acryl” and “methacryl,” the term “(meth)acrylate” means to encompass “acrylate” and “methacrylate,” and the term “(meth)acryloyl” means to encompass “acryloyl” and “methacryloyl.”

The term “acrylic polymer” means to encompass a polymer having a monomer unit derived from a (meth)acrylate, and means to encompass a (meth)acrylic copolymer.

### <<The Present Adhesive Sheet>>

The adhesive sheet according to an example of an embodiment of the present disclosure (also referred to as “the present adhesive sheet”) is an adhesive sheet formed from an adhesive composition [I] containing an acrylic polymer (A) and a radically polymerizable compound (B), and specifically useful as an adhesive sheet used for laminating a constituent member of a flexible image display device.

### <<Adhesive Composition [I]>>

The adhesive composition [I] contains the acrylic polymer (A) and the radically polymerizable compound (B), and preferably contains the acrylic polymer (A) as a main component.

### <Acrylic Polymer (A)>

The acrylic polymer (A) used in the present adhesive sheet is an acrylic polymer having: a structural portion derived from an alkyl (meth)acrylate (a1) with an alkyl group having 5 to 20 carbon atoms; and a structural portion derived from a hydroxy-group-containing (meth)acrylate (a2). The acrylic polymer (A) is preferably obtained by copolymerizing a mixture containing the alkyl (meth)acrylate (a1) with an alkyl group having 5 to 20 carbon atoms and the hydroxy-group-containing (meth)acrylate (a2) as copolymerization components to constitute the acrylic polymer (A). The acrylic polymer (A) may also be obtained by copolymerizing a monomer component (a3) other than the alkyl (meth)acrylate (a1) with an alkyl group having 5 to 20 carbon atoms and the hydroxy-group-containing (meth)acrylate (a2) therewith as the copolymerization components.

<Alkyl (Meth)Acrylate (a1) with Alkyl Group Having 5 to 20 Carbon Atoms>

Examples of the alkyl (meth)acrylate (a1) with an alkyl group having 5 to 20 carbon atoms include: linear alkyl (meth)acrylates such as n-pentyl (meth)acrylate, n-hexyl (meth)acrylate, n-heptyl (meth)acrylate, n-octyl (meth)acrylate, n-nonyl (meth)acrylate, and n-decyl (meth)acrylate; branched alkyl (meth)acrylates such as isopentyl (meth)acrylate, neopentyl (meth)acrylate, 2-ethylhexyl (meth)acrylate, isooctyl (meth)acrylate, isononyl (meth)acrylate, and isodecyl (meth)acrylate; and alicyclic (meth)acrylates such as cyclohexyl (meth)acrylate and t-butylcyclohexyl (meth)acrylate. These may be used alone, or two or more of these may be used in combination.

Among these, the linear alkyl (meth)acrylate or the branched alkyl (meth)acrylate is preferable in terms of adhesiveness, and a linear or branched alkyl (meth)acrylate with an alkyl group having 6 to 18, particularly 6 to 16, still particularly 8 to 12, carbon atoms is preferable.

Among these, the linear alkyl (meth)acrylate is preferable in terms of adhesiveness and recovering ability, and a linear alkyl (meth)acrylate with an alkyl group having 6 to 18, particularly 6 to 18, still particularly 8 to 12, carbon atoms is preferable in terms of inhibition of increase in the storage shearing elastic modulus (G′) at low temperature to improve bendability, and examples thereof include n-pentyl (meth)acrylate, n-hexyl (meth)acrylate, n-octyl (meth)acrylate, n-nonyl (meth)acrylate, and n-decyl (meth)acrylate. Among these, n-octyl (meth)acrylate, n-nonyl (meth)acrylate, and n-decyl (meth)acrylate are preferable, and n-octyl (meth)acrylate is particularly preferable.

From the viewpoint of inhibition of increase in the storage shearing elastic modulus (G′) at low temperature to improve bendability, acrylates are particularly preferable.

In the present adhesive sheet, a content of the alkyl (meth)acrylate (a1) with an alkyl group having 5 to 20 carbon atoms is preferably 50 to 95 mass % relative to an entirety of the copolymerization components constituting the acrylic polymer (A) in terms of inhibition of increase in the storage shearing elastic modulus (G′) at low temperature, and more preferably 60 to 90 mass %, and particularly preferably 70 to 85 mass %. The proportion of the alkyl (meth)acrylate (a1) is preferably not less than the above lower limit because increase in the storage shearing elastic modulus (G′) at low temperature can be inhibited, and the proportion is preferably not greater than the upper limit because other physical properties such as adhesiveness can be achieved at the same time.

<Hydroxy-Group-Containing (Meth)Acrylate (a2)>

Examples of the hydroxy-group-containing (meth)acrylate (a2) include: hydroxyalkyl (meth)acrylates, such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates, such as caprolactone-modified 2-hydroxyethyl (meth)acrylate; oxyalkylene-modified (meth)acrylates, such as diethylene glycol (meth)acrylate and polyethylene glycol (meth)acrylate; primary-hydroxy-group-containing (meth)acrylates, such as 2-acryloyloxyethyl-2-hydroxyethylphthalic acid; secondary-hydroxy-group-containing (meth)acrylates, such as 2-hydroxypropyl (meth)acrylate, 2-hydroxybutyl (meth)acrylate, and 3-chloro-2-hydroxypropyl (meth)acrylate; and tertiary-hydroxy-group-containing (meth)acrylates, such as 2,2-dimethyl-2-hydroxyethyl (meth)acrylate. These may be used alone, or two or more of these may be used in combination.

Among the hydroxy-group-containing (meth)acrylates (a2), primary-hydroxy-group-containing (meth)acrylates, such as for example, 2-hydroxyethyl (meth)acrylate, 4-hydroxybutyl (meth)acrylate, and 2-hydroxypropyl (meth)acrylate are preferable in terms of reduction in the storage shearing elastic modulus (G′) at low temperature. Particularly, hydroxy-group-containing (meth)acrylates having a hydroxyalkyl group having 1 to 10, further 1 to 6, particularly 2 to 4 carbon atoms, such as for example, 2-hydroxyethyl (meth)acrylate, and 4-hydroxybutyl (meth)acrylate are preferable, and 2-hydroxyethyl (meth)acrylate is particularly preferable.

A content of the hydroxy-group-containing (meth)acrylate (a2) is preferably 5 to 50 mass %, more preferably 10 to 40 mass %, and particularly preferably 15 to 30 mass % relative to an entirety of the copolymerization components of the acrylic polymer (A) in terms of adhesiveness. The content of this hydroxy-group-containing (meth)acrylate (a2) is preferably not less than the lower limit because high adhesiveness can be obtained, and the content is preferably not greater than the upper limit because an increase in the storage shearing elastic modulus (G′) at low temperature can be inhibited.

In the present adhesive sheet, a monomer component (a3) (except for the components (a1) and (a2)) copolymerizable with the alkyl (meth)acrylate (a1) with an alkyl group having 5 to 20 carbon atoms and/or the hydroxy-group-containing (meth)acrylate (a2) can be used in combination. Examples of such a monomer component (a3) include ethylenically unsaturated group monomers having a functional group other than a hydroxy group, alkyl (meth)acrylates having an alkyl group having 1 to 4 or not less than 20 carbon atoms, and other copolymerizable monomers. These may be used alone, or two or more of these may be used in combination.

Examples of the ethylenically unsaturated group monomer having a functional group other than a hydroxy group (hereinafter, may be referred to as “functional-group-containing ethylenically unsaturated monomer”) include a functional-group-containing monomer having a nitrogen atom, a carboxy-group-containing monomer, an acetoacetyl-group-containing monomer, and a glycidyl-group-containing monomer.

Among these, the functional-group-containing monomers having a nitrogen atom are preferable in terms of imparting an aggregation force and an effect of crosslinking acceleration, amino-group-containing monomers, amide-group-containing monomers, and isocyanate-group-containing monomers are more preferable, and amino-group-containing monomers are further preferable.

Examples of the amino-group-containing monomer as the functional-group-containing monomer having a nitrogen atom include: primary-amino-group-containing (meth)acrylates, such as aminomethyl (meth)acrylate and aminoethyl (meth)acrylate; secondary-amino-group-containing (meth)acrylates, such as t-butylaminoethyl (meth)acrylate and t-butylaminopropyl (meth)acrylate; and tertiary-amino-group-containing (meth)acrylates, such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropylacrylamide.

Examples of the amide-group-containing monomer include: (meth)acrylamide; N-alkyl (meth)acrylamides, such as N-methyl(meth)acrylamide, N-ethyl (meth)acrylamide, N-propyl(meth)acrylamide, N-n-butyl (meth)acrylamide, diacetone(meth)acrylamide, and N,N′-methylenebis(meth)acrylamide; N,N-dialkyl(meth)acrylamides, such as N, N-dimethyl(meth)acrylamide, N,N-diethyl(meth)acrylamide, N,N-dipropyl(meth)acrylamide, N,N-ethylmethylacrylamide, and N, N-diallyl(meth)acrylamide; hydroxyalkyl(meth)acrylamides, such as N-hydroxymethyl(meth)acrylamide and N-hydroxyethyl(meth)acrylamide; and alkoxyalkyl(meth)acrylamides, such as N-methoxymethyl(meth)acrylamide and N-(n-butoxymethyl) (meth)acrylamide.

Examples of the isocyanate-group-containing monomer include 2-(meth)acryloyloxyethyl isocyanate and alkylene oxide adduct thereof.

The isocyanate group may be protected with a blocking agent, such as methyl ethyl ketone oxime, 3,5-dimethylpyrazole, 1,2,4-triazole, and diethyl malonate.

Examples of the carboxy-group-containing monomer include (meth)acrylic acid, carboxyethyl (meth)acrylate, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, 2-(meth)acryloyloxypropylsuccinic acid, crotonic acid, fumaric acid, maleic acid, itaconic acid, monomethyl maleate, and monomethyl itaconate.

Examples of the acetoacetyl-group-containing monomer include 2-(acetoacetoxy)ethyl (meth)acrylate and allyl acetoacetate.

Examples of the glycidyl-group-containing monomer include glycidyl (meth)acrylate and allylglycidyl (meth)acrylate.

These functional-group-containing ethylenically unsaturated monomers may be used alone, or two or more of these may be used in combination.

An upper limit of a content of the functional group-containing ethylenically unsaturated monomer is preferably not greater than 30 mass %, more preferably not greater than 20 mass %, further preferably not greater than 10 mass %, and particularly preferably not greater than 5 mass % relative to the entirety of the copolymerization components of the acrylic polymer (A) from the viewpoint of reduction in decrease in adhesiveness due to bleed out. A lower limit thereof is typically 0 mass %.

Examples of the alkyl (meth)acrylates having an alkyl group having 1 to 4 or greater than 20 carbon atoms include: linear alkyl (meth)acrylates, such as methyl(meth)acrylate, ethyl (meth)acrylate, n-propyl (meth)acrylate, n-butyl (meth)acrylate, and icosyl (meth)acrylate; and branched alkyl (meth)acrylates, such as isopropyl (meth)acrylate, isobutyl (meth)acrylate, sec-butyl (meth)acrylate, t-butyl (meth)acrylate, and isoicosyl (meth)acrylate.

These may be used alone, or two or more of these may be used in combination.

When the alkyl (meth)acrylate having an alkyl group having 1 to 4 or greater than 20 carbon atoms is contained, an upper limit of a content thereof is preferably not greater than 20 mass %, more preferably not greater than 10 mass %, and further preferably not greater than 5 mass % relative to the entirety of the copolymerization components of the acrylic polymer (A) from the viewpoint of keeping the recovering ability. The lower limit is typically 0 mass %.

Examples of the other copolymerizable monomer include: aromatic (meth)acrylates, such as phenyl (meth)acrylate, benzyl (meth)acrylate, phenoxyethyl (meth)acrylate, phenyl diethylene glycol (meth)acrylate, phenoxy polyethylene glycol (meth)acrylate, phenoxy polyethylene glycol-polypropylene glycol (meth)acrylate, and nonylphenol ethylene oxide-adduct (meth)acrylate; (meth)acrylates having a benzophenone structure, such as 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloyloxyethoxybenzophenone, 4-methacryloyloxy-4′-methoxybenzophenone, 4-methacryloyloxyethoxy-4′-methoxybenzophenone, 4-methacryloyloxy-4′-bromobenzophenone, 4-methacryloyloxyethoxy-4′-bromobenzophenone, and a mixture thereof; and vinyl monomers, such as acrylonitrile, methacrylonitrile, styrene, α-methylstyrene, vinyl stearate, vinyl propionate, vinyl acetate, vinyl chloride, vinylidene chloride, alkyl vinyl ether, vinyltoluene, vinylpyridine, vinylpyrrolidone, itaconic acid dialkyl ester, fumaric acid dialkyl ester, allyl alcohol, acryl chloride, methyl vinyl ketone, N-acrylamidomethyltrimethylammonium chloride, allyltrimethylammonium chloride, and dimethylallyl vinyl ketone. These may be used alone, or two or more of these may be used in combination.

Among these, containing a nitrogen-containing vinyl monomer such as vinylpyridine and vinylpyrrolidone tends to form a hydrogen bond with the hydroxy-group-containing (meth)acrylate (a2) to improve adhesiveness and aggregation property of the adhesive sheet.

An upper limit of the other copolymerizable monomer when contained is preferably not greater than 20 mass %, more preferably not greater than 15 mass %, further preferably not greater than 10 mass %, and particularly preferably not greater than 5 mass % relative to the entirety of the copolymerization components of the acrylic polymer (A) from the viewpoint of improvement of flexibility and stress-relaxing ability. The lower limit is typically 0 mass %.

The acrylic polymer (A) can be prepared by copolymerizing the aforementioned monomers by a conventionally known polymerization method, such as, for example, solution radical polymerization, suspension polymerization, bulk polymerization, and emulsion polymerization.

In the acrylic polymer (A), a photoactive portion, for example a polymerizable carbon double bond group, may be introduced on a side chain. This photoactive portion can enhance crosslinking efficiency of the adhesive composition [I] and crosslink the adhesive composition [I] in a shorter time, which can improve the productivity.

Examples of a method for introducing the polymerizable carbon double bond group on the side chain of the acrylic polymer (A) include a method including: producing a copolymer having the aforementioned hydroxy-group-containing (meth)acrylate (a2) and functional-group-containing ethylenically unsaturated monomer; and then subjecting a compound having a functional group that can react with these functional groups and the polymerizable carbon double bond group to condensation or an addition reaction while keeping the activity of the polymerizable carbon double bond group.

Examples of combinations of these functional groups include an epoxy group (glycidyl group) and a carboxy group, an amino group and a carboxy group, an amino group and an isocyanate group, an epoxy group (glycidyl group) and an amino group, a hydroxy group and an epoxy group, and a hydroxy group and an isocyanate group. Among these combinations of the functional groups, the combination of a hydroxy group and an isocyanate group is preferable in terms of ease of reaction control. Specifically, a combination in which the copolymer has a hydroxy group and the compound has an isocyanate group is preferable.

Examples of the isocyanate compound having the polymerizable carbon double bond group include the aforementioned 2-(meth)acryloyloxyethyl isocyanate and alkylene oxide adducts thereof.

A content of the compound having the functional group that can react with the functional group and the polymerizable carbon double bond group is preferably not greater than 10 parts by mass, more preferably not greater than 5 parts by mass, further preferably not greater than 1 part by mass, and particularly preferably not greater than 0.1 part by mass relative to 100 parts by mass of the acrylic polymer (A) from the viewpoint of improvement of the adhesiveness and stress-relaxing ability. The lower limit is typically 0 parts by mass.

A glass transition temperature (Tg) of the acrylic polymer (A) is preferably not higher than −10° C., more preferably not higher than −20° C., further preferably lower than −25° C., particularly preferably not higher than-27° C., and most preferably not higher than −30° C. in terms of inhibition of increase in the storage shearing elastic modulus (G′) at low temperature. The Tg is obtained by a dynamic viscoelasticity measurement with a shearing mode at a frequency of 1 Hz and being defined by a maximum point of a loss tangent (tan δ). With considering glue ooze, etc., a lower limit of the glass transition temperature (Tg) is typically −50° C., and preferably −45° C.

In the present adhesive sheet, the glass transition temperature (Tg) of the acrylic polymer (A) can be determined by using a dynamic viscoelasticity measurement apparatus and reading a temperature at which a loss tangent (loss shearing elastic modulus G″/storage shearing elastic modulus G′=tan δ) when the dynamic viscoelasticity measured with a shearing mode at a frequency of 1 Hz becomes maximum.

For example, the acrylic polymer (A) is molded into a cylinder with 8 mm in diameter (height: 1.0 mm), and a loss tangent (tan δ) of this cylinder can be measured by using a viscoelasticity measuring apparatus (trade name: “DHR 2” available from T.A. Instruments) under the following measurement conditions.

### (Measurement Conditions)

Measurement tool: Ø 8 mm parallel plate
Strain: 0.1%
Frequency: 1 Hz
Measurement temperature: −60 to 100° C.
Temperature raising rate: 5° C./min

A theoretical Tg of the acrylic polymer (A) is preferably not higher than −52° C., more preferably not higher than −54° C., and further preferably not higher than −56° C. in terms of reduction in increase in the storage shearing elastic modulus (G′) at low temperature. With considering glue ooze, etc., a lower limit of the theoretical Tg of the acrylic polymer (A) is typically −70° C., and preferably −65° C.

The theoretical Tg of the acrylic polymer (A) means a value calculated from a glass transition temperature and constitution ratio of a polymer obtained from a homopolymer of each of the copolymer components with a Fox calculation formula.

The Fox calculation formula is a calculated value determined with the following formula, and can be determined by using a value described in Polymer Hand Book [Polymer Hand Book, J. Brandrup, Interscience, 1989].

$$( Formula ) 1 / ( 273 + T g ) = Σ ( W i / ( 273 + T g i ) ) ,$$

wherein Wi represents a weight fraction of a monomer “i,” and Tgi represents Tg (° C.) of a homopolymer of the monomer “i.”

A weight-average molecular weight (Mw) of the acrylic polymer (A) is preferably not less than 600,000, more preferably not less than 700,000, and further preferably not less than 800,000 from the viewpoint of obtaining an adhesive composition [I] with a high aggregation property.

An upper limit of the weight-average molecular weight (Mw) of the acrylic polymer (A) is preferably not greater than 1,500,000, more preferably not greater than 1,200,000, and further preferably 1,100,000 in view of operability and uniform stirring ability.

In the present adhesive sheet, the weight-average molecular weight (Mw) can be determined as follows, for example.

### (Method for Measuring Weight-Average Molecular Weight)

A measurement sample is prepared by dissolving 4 mg of the acrylic polymer (A) in 12 mL of tetrahydrofuran (THF), and measuring a molecular weight distribution curve under the following conditions by using a gel permeation chromatography (GPC) analyzer (HLC-8320 GPC available from Tosoh Co. Ltd.) to determine the weight-average molecular weight (Mw).
Guard column: TSK guard column HXL
Separation column: TSK gel GMHXL (four columns)
Temperature: 40° C.
Injection amount: 100 μL
In terms of polystyrene standard
Solvent: THF
Flow rate: 1.0 mL/minute

### <Radically Polymerizable Compound (B)>

The adhesive composition [I] contains a radically polymerizable compound (B) in addition to the acrylic polymer (A). This radically polymerizable compound (B) allows the adhesive composition [I] to form a crosslinked structure to impart aggregation ability and high recovering ability in bending to the adhesive layer (adhesive sheet). The adhesive layer having appropriate aggregation ability can prevent glue ooze when rolled, and can keep good adhesiveness. In addition, the high recovering ability in bending can improve a folding trace and prevent delamination in the bending portion.

It is important that the radically polymerizable compound (B) contains a di(meth)acrylate (B1) having an alkylene group having 2 to 4 carbon atoms (hereinafter, may be abbreviated as “di(meth)acrylate (B1)”), and this di(meth)acrylate (B1) can further improve the adhesiveness while having good flexibility and recovering ability.

Although any of a di(meth)acrylate having a linear alkylene group and a di(meth)acrylate having a branched alkylene group may be used as the di(meth)acrylate (B1), the di(meth)acrylate having a linear alkylene group is preferable in terms of the recovering ability.

Specific examples of the di(meth)acrylate having a linear alkylene group include ethanediol di(meth)acrylate, propanediol di(meth)acrylate, and butanediol di(meth)acrylate. Among these, butanediol di(meth)acrylate is preferable in terms of adhesiveness, versatility, recovering ability, and low storage shearing elastic modulus (G′) at low temperature. Further, acrylates are particularly preferable form the viewpoint of inhibition of increase in the storage shearing elastic modulus (G′) at low temperature to improve bendability. These may be used alone or in combination.

As the radically polymerizable compound (B), a radically polymerizable compound (B2) other than the di(meth)acrylate (B1) may be used in combination.

Examples of the radically polymerizable compound (B2) other than the di(meth)acrylate (B1) include: di(meth)acrylates having an alkylene group having 1 or not less than 5 carbon atoms; and (meth)acrylic monomers and (meth)acrylic oligomers having two or more functional groups. These may be used alone or in combination.

Examples of the di(meth)acrylate having an alkylene group having 1 or not less than 5 carbon atoms include methanediol di(meth)acrylate, pentanediol di(meth)acrylate, hexanediol di(meth)acrylate, heptanediol di(meth)acrylate, octanediol di(meth)acrylate, nonanediol di(meth)acrylate, decanediol di(meth)acrylate, undecanediol di(meth)acrylate, and dodecanediol di(meth)acrylate.

Examples of the (meth)acrylic monomer having two or more functional groups include glycerol di(meth)acrylate, neopentyl glycol di(meth)acrylate, glycerol glycidyl ether di(meth)acrylate, tricyclodecane dimethacrylate, tricyclodecanedimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, trimethylolpropane trioxyethyl (meth)acrylate, ε-caprolactone-modified tris(2-hydroxyethyl) isocyanurate tri (meth)acrylate, pentaerythritol tri (meth)acrylate, propoxylated pentaerythritol tri (meth)acrylate, ethoxylated pentaerythritol tri (meth)acrylate, pentaerythritol tetra(meth)acrylate, propoxylated pentaerythritol tetra(meth)acrylate, ethoxylated pentaerythritol tetra(meth)acrylate, dipentaerythritol hexa (meth)acrylate, polyethylene glycol di(meth)acrylate, polypropylene glycol di(meth)acrylate, polytetramethylene glycol di(meth)acrylate, tris(acryloxyethyl) isocyanurate, dipentaerythritol hexa (meth)acrylate, dipentaerythritol penta (meth)acrylate, tripentaerythritol hexa (meth)acrylate, tripentaerythritol penta (meth)acrylate, neopentyl glycol hydroxypivalate di(meth)acrylate, di(meth)acrylate of ε-caprolactone adduct of neopentyl glycol hydroxypivalate, trimethylolpropane tri(meth)acrylate, trimethylolpropane polyethoxy tri(meth)acrylate, and ditrimethylolpropane tetra(meth)acrylate.

Examples of the (meth)acrylic oligomer having two or more functional groups include polyfunctional (meth)acrylate oligomers, such as polyester (meth)acrylate oligomers, epoxy (meth)acrylate oligomers, urethane (meth)acrylate oligomers, and polyether (meth)acrylate oligomers.

Among these, urethane (meth)acrylate oligomers are preferable from the viewpoint of imparting appropriate toughness to the cured product.

A content of the radically polymerizable compound (B) is preferably not less than 0.1 part by mass, more preferably not less than 0.5 parts by mass, and further preferably not less than 1 part by mass relative to 100 parts by mass of the acrylic polymer (A) from the viewpoints of shape stability of the adhesive sheet and imparting durability to the laminated sheet. The upper limit is preferably not greater than 10 parts by mass, more preferably not greater than 7 parts by mass, particularly preferably not greater than 5 parts by mass, and further preferably not greater than 3 parts by mass in terms of reduction in the storage shearing elastic modulus (G′) at low temperature.

It is important to use the di(meth)acrylate (B1) as the radically polymerizable compound (B), and a content of the di(meth)acrylate (B1) is preferably not less than 0.1 part by mass, more preferably not less than 0.5 parts by mass, further preferably not less than 0.7 parts by mass, and particularly preferably not less than 1 part by mass relative to 100 parts by mass of the acrylic polymer (A). In terms of keeping high adhesiveness, the upper limit is preferably not greater than 10 parts by mass, more preferably not greater than 7 parts by mass, particularly preferably not greater than 5 parts by mass, and further preferably not greater than 3 parts by mass.

The di(meth)acrylate (B1) is preferably used as a main component of the radically polymerizable compound (B), and only the di(meth)acrylate (B1) is particularly preferably used as the radically polymerizable compound (B).

In addition to the radically polymerizable compound (B), a thermal crosslinker can be used in combination in terms of further improvement of the crosslinking density to improve long-term reliability.

Examples of such a thermal crosslinker include isocyanate crosslinker, epoxy crosslinker, aziridine crosslinker, melamine crosslinker, aldehyde crosslinker, amine crosslinker, and metal chelate crosslinker. Among these, isocyanate crosslinker is preferably used in terms of excellent reactivity with the acrylic polymer (A).

### <Photopolymerization Initiator (C)>

In the present adhesive sheet, a photopolymerization initiator (C) is preferably further contained in addition to the acrylic polymer (A) and the radically polymerizable compound (B). The photopolymerization initiator (C) may be any compound that generates radicals with active energy radiation.

The photopolymerization initiator (C) is largely classified into two types with its radical generation mechanism: a cleavage-type photopolymerization initiator in which a single bond in the initiator itself can be cleaved and decomposed to generate radicals; and a hydrogen abstraction-type photopolymerization initiator in which an excited initiator and a hydrogen donner in the system can form an exciplex to transfer hydrogen in the hydrogen donner.

The photopolymerization initiator (C) may be any of the cleavage-type photopolymerization initiator and the hydrogen abstraction-type photopolymerization initiator, each of them may be used singly or may be mixed for use, and one or more of them may be each used in combination.

In the present adhesive sheet, the hydrogen abstraction-type photopolymerization initiator is preferably used in terms of efficient crosslinking without requiring a functional group such as a polymerizable carbon double bond group in the acrylic polymer (A) itself.

Examples of the cleavage-type photopolymerization initiator include 2,2-dimethoxy-1,2-diphenylethan-1-one, 1-hydroxycyclohexyl phenyl ketone, 2-hydroxy-2-methyl-1-phenylpropan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl}phenyl]-2-methylpropan-1-one, oligo (2-hydroxy-2-methyl-1-(4-(methylvinyl)phenyl) propanone), methyl phenylglyoxylate, 2-benzyl-2-dimethylamino-1-(4-morpholinophenyl) butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl) ethoxyphenylphosphine oxide, bis(2,6-dimethoxybenzoyl)-2,4,4-trimethylpentylphosphine oxide, and derivatives thereof.

Examples of the hydrogen abstraction-type photopolymerization initiator include benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetate)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, and derivatives thereof. Among these, a benzophenone-type hydrogen abstraction-type photopolymerization initiator is preferable, and 4-methylbenzophenone and 2,4,6-trimethylbenzophenone are more preferable.

A content of the photopolymerization initiator (C) is preferably typically 0.1 to 10 parts by mass, specifically 0.5 to 5 parts by mass, and more specifically 1 to 3 parts by mass relative to 100 parts by mass of the acrylic polymer (A). The content of not less than the above lower limit tends to prevent curing failure, and the content of not greater than the above upper limit tends to easily inhibit a decrease in solution stability, such as precipitation from the adhesive composition [I], to inhibit problems of embrittlement and coloring.

### <Other Components>

The adhesive component [I] can appropriately contain various additives as “other components” as necessary at an extent not impairing the effect of the present disclosure. Examples of the other components include plasticizer, silane-coupling agent, UV absorber, antirust agent, tackifier resin, antioxidant, light stabilizer, metal deactivator, antiaging agent, moisture absorber, and inorganic particles.

As necessary, reaction catalysts such as tertiary amine compound, quaternary ammonium compound, and tin laurate compound may be appropriately contained.

These may be used alone, or two or more of these may be used in combination.

### (Plasticizer)

The plasticizer is a material for softening a resin with a high elastic modulus to improve processability and flexibility. Examples of the plasticizer include monofunctional (meth)acrylic oligomers such as polyester (meth)acrylate, urethane (meth)acrylate, and polyether (meth)acrylate. Among these, the urethane (meth)acrylate oligomer is preferable from the viewpoint of imparting appropriate toughness to the cured product.

### (Silane-Coupling Agent)

The silane-coupling agent is an organic silicon compound having one or more reactive functional groups and one or more alkoxy groups bonded to a silicon atom in the structure. Examples of the reactive functional group include epoxy group, (meth)acryloyl group, mercapto group, hydroxy group, carboxy group, amino group, amide group, and isocyanate group. Among these, epoxy group and mercapto group are preferable in terms of balance of durability.

As the alkoxy group bonded to a silicon atom, an alkoxy group having 1 to 8 carbon atoms is preferably contained in terms of durability and storage stability, and a methoxy group and an ethoxy group are particularly preferable. The silane-coupling agent may have an organic substituent other than the reactive functional group and the alkoxy group bonded to a silicon atom, such as, for example, alkyl group and phenyl group.

Examples of the silane-coupling agent used in the present adhesive sheet include: monomer-type epoxy group-containing silane-coupling agents being silane compounds such as 3-glycidoxypropyltrimethoxysilane, 3-glycidoxypropyltriethoxysilane, 3-glycidoxypropylmethyldiethoxysilane, 3-glycidoxypropylmethyldimethoxysilane, and 2-(3,4-epoxycyclohexyl)ethyltrimethoxysilane; oligomer-type epoxy group-containing silane-coupling agents being silane compounds in which a part of the above silane compound is hydrolytically condensing-polymerized or in which the above silane compound and an alkyl group-containing silane compound, such as methyltriethoxysilane, ethyltriethoxysilane, methyltrimethoxysilane, and ethyltrimethoxysilane, are co-condensed; monomer-type mercapto group-containing silane-coupling agents being silane compounds such as 3-mercaptopropyltrimethoxysilane, 3-mercaptopropyltriethoxysilane, γ-mercaptopropyldimethoxymethylsilane, and 3-mercaptopropylmethyldimethoxysilane; oligomer-type mercapto group-containing silane-coupling agents being silane compounds in which a part of the above silane compound is hydrolytically condensing-polymerized or in which the above silane compound and an alkyl group-containing silane compound, such as methyltriethoxysilane, ethyltriethoxysilane, methyltrimethoxysilane, and ethyltrimethoxysilane, are co-condensed; (meth)acryloyl group-containing silane-coupling agents, such as 3-acryloxypropyltrimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane; amino group-containing silane-coupling agents, such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene) propylamine, and N-phenyl-3-aminopropyltrimethoxysilane; isocyanate group-containing silane-coupling agents, such as 3-isocyanatepropyltriethoxysilane; and vinyl group-containing silane-coupling agents, such as vinyltrimethoxysilane and vinyltriethoxysilane.

These may be used alone, or two or more of these may be used in combination.

Among these, the epoxy group-containing silane-coupling agent and the mercapto group-containing silane coupling agent are preferably used, and specifically, the epoxy group-containing silane-coupling agent is preferable in terms of excellent durability.

A content of the silane-coupling agent is preferably 0.005 to 10 parts by mass, particularly preferably 0.01 to 5 parts by mass, and further preferably 0.05 to 1 part by mass relative to 100 parts by mass of the acrylic polymer (A). The content within the above range tends to improve durability, and the content of not greater than the above upper limit tends to improve durability.

### (UV Absorber)

Examples of the UV absorber include benzophenone-based UV absorbers, benzotriazole-based UV absorbers, triazine-based UV absorbers, salicylic acid-based UV absorbers, cyanoacrylate-based UV absorbers, and benzoxazine-based UV absorbers. These UV absorbers may be used alone, or two or more of these may be used in combination.

A content of the UV absorber is preferably 0.01 to 20 parts by mass, particularly preferably 0.1 to 15 parts by mass, and further preferably 0.5 to 10 parts by mass relative to 100 parts by mass of the acrylic polymer (A). The content of not less than the above lower limit tends to improve light-resistant reliability, and the content of not greater than the above upper limit tends to improve yellowing resistance.

### (Antirust Agent)

The antirust agent is preferably triazoles and benzotriazoles, for example. The antirust agent can prevent corrosion of an optical member. A content of the antirust agent is preferably 0.01 to 5 parts by mass, and specifically preferably not less than 0.1 part by mass and not greater than 3 parts by mass relative to 100 parts by mass of the acrylic polymer (A).

A content of the other components is preferably not greater than 5 parts by mass, particularly preferably not greater than 1 part by mass, and further preferably not greater than 0.5 parts by mass relative to 100 parts by mass of the acrylic polymer (A). An excessively large content thereof tends to decrease compatibility with the acrylic polymer (A) to deteriorate durability.

The adhesive composition [I] is prepared by mixing predetermined amounts of the acrylic polymer (A), the radically polymerizable compound (B), preferably additionally the photopolymerization initiator (C), and as necessary, the other components such as the silane-coupling agent, the UV absorber, and the antirust agent.

The adhesive composition [I] obtained as above is subjected to the adhesive sheet, specifically the adhesive sheet used for laminating the constituent member of the flexible image display device.

### <Constitution>

The present adhesive sheet may be a single-layer sheet composed of only an adhesive layer formed from the adhesive composition [I] (also referred to as “the present adhesive layer”) or may be a multilayer sheet in which a plurality of the present adhesive layers is laminated. The present adhesive sheet may also be a multilayer sheet in which the present adhesive layer and an adhesive layer other than the present adhesive layer are laminated.

### <Physical Properties of the Present Adhesive Sheet>

The present adhesive sheet can have the following physical properties.

### (Storage Shearing Elastic Modulus)

The present adhesive sheet preferably has a storage shearing elastic modulus at −40° C. [G′(−40° C.)] obtained by dynamic viscoelasticity measurement with a shearing mode at a frequency of 1 Hz of not greater than 50,000 kPa. The storage shearing elastic modulus [G′(−40° C.)] of the present adhesive sheet within the above range can reduce an interlayer stress in folding of the laminated sheet or the flexible image display device member specifically under a low-temperature environment when the present adhesive sheet adheres to the member sheet to form the laminated sheet or the flexible image display device member, for example. Accordingly, delamination and cracking of the member sheet and the flexible member can be reduced.

From such a viewpoint, the storage shearing elastic modulus at −40° C. [G′(−40° C.)] of the present adhesive sheet obtained by dynamic viscoelasticity measurement with a shearing mode at a frequency of 1 Hz is preferably not greater than 40,000 kPa, more preferably not greater than 30,000 kPa, further preferably not greater than 10,000 kPa, particularly preferably not greater than 9,000 kPa, and most preferably not greater than 8,000 kPa.

A lower limit of the storage shearing elastic modulus [G′(−40° C.)] of the present adhesive sheet is preferably not less than 100 kPa in terms of a balance with a storage shearing elastic modulus at high temperature.

The present adhesive sheet has a storage shearing elastic modulus at −20° C. [G′(−20° C.)] obtained by dynamic viscoelasticity measurement with a shearing mode at a frequency of 1 Hz of not greater than 700 kPa. The dynamic viscoelasticity measurement is preferably not greater than 600 kPa, more preferably not greater than 500 kPa, further preferably not greater than 400 kPa, particularly preferably not greater than 300 kPa, and still further preferably not greater than 200 kPa.

A lower limit of the storage shearing elastic modulus [G′(−20° C.)] of the present adhesive sheet is preferably not less than 50 kPa from the viewpoints of prevention of glue ooze and shape retention of the adhesive sheet.

The storage shearing elastic modulus [G′(−20° C.)] of the present adhesive sheet within the above range can reduce an interlayer stress in folding the laminated sheet or the flexible image display device member particularly from low temperature to high temperature where the present adhesive sheet adheres to the member sheet to form the laminated sheet or the flexible image display device member, for example. Accordingly, delamination and cracking of the member sheet or the flexible member can be inhibited.

The present adhesive sheet has a storage shearing elastic modulus at 25° C. [G′ (25° C.)] obtained by dynamic viscoelasticity measurement with a shearing mode at a frequency of 1 Hz of preferably not greater than 100 kPa, particularly preferably not greater than 50 kPa, further preferably not greater than 40 kPa, and still further preferably not greater than 30 kPa from the viewpoint of obtaining high adhesiveness.

A lower limit of the storage shearing elastic modulus [G′ (25° C.)] of the present adhesive sheet is preferably not less than 5 kPa from the viewpoints of prevention of glue ooze and shape retention of the adhesive sheet.

The present adhesive sheet has a storage shearing elastic modulus at 80° C. [G′ (80° C.)] obtained by dynamic viscoelasticity measurement with a shearing mode at a frequency of 1 Hz of preferably not greater than 100 kPa, particularly preferably not greater than 50 kPa, further preferably not greater than 30 kPa, and still further preferably not greater than 20 kPa from the viewpoint of obtaining high adhesiveness.

A lower limit of the storage shearing elastic modulus [G′ (80° C.)] of the present adhesive sheet is preferably not less than 1 kPa from the viewpoints of prevention of glue ooze and shape retention of the adhesive sheet.

### (Loss Shearing Elastic Modulus)

In the present adhesive sheet, a loss shearing elastic modulus at 23° C. [G″(23° C.)] obtained by dynamic viscoelasticity measurement with a shearing mode at a frequency of 1 Hz is preferably not less than 8 kPa, further preferably not less than 10 kPa, and particularly preferably not less than 12 kPa. On the other hand, an upper limit of the loss shearing elastic modulus [G″(23° C.)] is preferably not greater than 400 kPa from the viewpoint of reduction in stress in bending.

The loss shearing elastic modulus [G″(23° C.)] of the present adhesive sheet within the above range can further increase adhesiveness of the present adhesive sheet.

### (Maximum Point of Loss Tangent (Tan δ) and Glass Transition Temperature (Tg))

In the present adhesive sheet, a loss tangent (tan δ) obtained by dynamic viscoelasticity measurement with a shearing mode at a frequency of 1 Hz preferably has a maximum point at preferably not higher than −25° C., and further preferably not higher than −30° C. The lower limit is typically-50° C.

This maximum point of the loss tangent (tan δ) can be interpreted as a glass transition temperature (Tg). The glass transition temperature (Tg) within the above range facilitates regulation of the storage shearing elastic modulus [G′(−20° C.)] of the present adhesive sheet to not greater than 700 kPa, particularly not greater than 500 kPa.

When the loss tangent (tan δ) obtained by dynamic viscoelasticity measurement with a shearing mode at a frequency of 1 Hz has only one observed inflection point, in other words, when the tan δ curve exhibits a single-peak shape, the glass transition temperature (Tg) can be considered to be single.

The “maximum point” of the loss tangent (tan δ) means a peak value in the tan δ curve, namely a point having a maximum value among inflection points where a differentiated value changes from positive (+) to negative (−) in a predetermined range or in an entire range.

The elastic moduli (storage shearing elastic moduli) G′ at various temperatures, the viscosity (loss shearing elastic modulus) G″, and tan δ=G″/G′ can be measured by using a strain rheometer.

The storage shearing elastic modulus (G′), the loss shearing elastic modulus (G″), and the loss tangent (tan δ) can be regulated within the above ranges by regulating types, weight-average molecular weights, etc., of the components of the adhesive composition [I] (for example, the acrylic polymer (A) and the radically polymerizable compound (B)) constituting the present adhesive sheet, or further regulating a gel fraction, etc., of the adhesive sheet. The method for regulation is not limited to these methods.

### (Recovering Ability)

Recovering ability of the present adhesive sheet can be measured by applying shearing strain corresponding to a seven-fold thickness at 25° C. for 10 minutes, and then reading a strain value (remained strain value) 10 minutes after the stress is removed. The recovering ability can be determined with the following formula.

$$Recovering rate ( \% ) = [ ( 700 - Remained strain value ) / 700 ] \times 100$$

The present adhesive sheet having such recovering ability can be an adhesive sheet having excellent recovering ability without remaining folding trace due to leaving in a bending state even when the present adhesive sheet adheres to the member sheet and is subjected to folding operation at low temperature or high temperature.

From such a viewpoint, the recovering ability is preferably not less than 20%, not less than 40%, particularly preferably not less than 50%, and further preferably not less than 70%, the recovering ability being calculated from remained strain values at 10 minutes after applying shearing strain corresponding to a seven-fold thickness at 25° C. for 10 minutes and then removing a stress. Since a higher recovering ability is more preferable, the upper limit is 100%.

### (Gel Fraction)

A gel fraction of the present adhesive sheet is preferably 30 to 95 mass %, more preferably 50 to 90 mass %, further preferably 55 to 85 mass %, and particularly preferably 60 to 85 mass %. The present adhesive sheet having a gel fraction of not less than the above lower limit can sufficiently retain the shape. The present adhesive sheet having a gel fraction of not greater than the upper limit can increase adhesiveness.

From the viewpoint of improvement of the recovering ability, the gel fraction of the present adhesive sheet is preferably 30 to 65 mass %, and more preferably 35 to 60 mass %.

The gel fraction is an indicator of a crosslinking degree (degree of curing), and can be measured under measurement conditions in the Example, described later.

### (Total Light Transmittance, Haze)

A total light transmittance of the present adhesive sheet is preferably not less than 85%, further preferably not less than 88%, and more preferably not less than 90%.

A haze of the present adhesive sheet is preferably not greater than 1.0%, further preferably not greater than 0.8%, and particularly preferably not greater than 0.5%.

The present adhesive sheet having a haze of not greater than 1.0% can be used for an image display device.

For regulating the haze of the present adhesive sheet within the above range, the present adhesive sheet preferably contains no particles such as organic particles.

### <Thickness>

A thickness of the present adhesive sheet is not particularly limited. The thickness of not less than 10 μm yields good handleability, and the thickness of not greater than 1,000 μm can contribute to thinning of the present adhesive sheet.

Thus, the thickness of the present adhesive sheet is preferably not less than 10 μm, more preferably not less than 15 μm, particularly preferably not less than 20 μm, and furthermore preferably not less than 25 μm.

The upper limit is preferably not greater than 1,000 μm, specifically preferably not greater than 500 μm, particularly preferably not greater than 250 μm, further preferably not greater than 100 μm, and still further preferably not greater than 50 μm.

### <Preferable Use of the Present Adhesive Sheet>

The present adhesive sheet is used for laminating a member constituting a display member (also referred to as “display member”), specifically a flexible member for a display used for producing the display. The present adhesive sheet is used as an adhesive part for the flexible display used for producing the flexible display.

The flexible member the same as those described later can be used.

### <Method for Manufacturing the Present Adhesive Sheet>

Next, a method for manufacturing the present adhesive sheet will be described.

The following description is an example of the method for manufacturing the present adhesive sheet, and the present adhesive sheet is not limited to the adhesive sheet manufactured by the following manufacturing method.

For producing the present adhesive sheet, the adhesive composition [I] for forming the present adhesive sheet containing the acrylic polymer (A) and radically polymerizable compound (B), the photopolymerization initiator (C), and other components as necessary is prepared, this adhesive composition [I] is formed into a sheet, and the sheet is subjected to crosslinking, namely a polymerization reaction to be cured and appropriately processed as necessary to produce the present adhesive sheet.

For producing the present adhesive sheet, the adhesive composition [I] for forming the present adhesive sheet is prepared in the same manner as above, this composition is applied on the member sheet or the flexible member, and this adhesive composition [I] is cured to form the present adhesive sheet.

Note that the method is not limited to this method.

When the adhesive composition [I] for forming the present adhesive sheet is prepared, the raw materials may be kneaded by using a temperature-controllable kneader (for example, a uniaxial extruder, a biaxial extruder, a planetary mixer, a biaxial mixer, and a pressurizing kneader).

When the raw materials are mixed, the additives such as the silane-coupling agent and the antioxidant may be blended with the resin in advance and then supplied into the kneader, all the materials may be melt-mixed in advance and then supplied, or only the additives may be condensed into the resin in advance to produce a master batch and then supplied.

As the method for forming the adhesive composition [I] into a sheet, a known method can be used, such as a wet-laminating method, a dry-laminating method, an extrusion casting method using a T-die, an extrusion laminating method, a calendar method, an inflation method, an injection molding method, and a liquid-injecting curing method. Among these, a wet-laminating method, an extrusion casting method, and an extrusion laminating method are preferable for manufacturing the sheet.

The adhesive composition [I] can be cured by irradiation with active energy radiation to manufacture a cured product. In addition to the irradiation with active energy radiation, heating may be performed for further curing.

Specifically, the present adhesive sheet can be manufactured by irradiating a formed product of the adhesive composition [I], for example a sheet, with active energy radiation. In addition to the irradiation with active energy radiation, heating may be performed for further curing.

Irradiation energy, an irradiation time, an irradiation method, etc., of the active energy radiation are not particularly limited as long as the photopolymerization initiator (C) is activated to polymerize the monomer components.

When the hydrogen abstraction-type photopolymerization initiator is used as the photopolymerization initiator (C), the acrylic polymer (A) is also subjected to the hydrogen abstraction reaction and the acrylic polymer (A) is incorporated into the crosslinked structure, which can form a crosslinked structure with many crosslinking points.

Therefore, the present adhesive sheet is preferably a cured product produced by using the hydrogen abstraction-type photopolymerization initiator.

As another embodiment of the method for manufacturing the present adhesive sheet, the adhesive composition [I] can be dissolved in an appropriate solvent and coated by using various coating methods.

When the coating method is used, the present adhesive sheet can also be obtained by thermal curing in addition to the curing by the aforementioned irradiation with the active energy radiation. In the case of coating, the thickness of the present adhesive sheet can be regulated by a coating thickness and a solid-content concentration of the coating liquid.

For example, the adhesive composition [I] is dissolved in a solvent, then applied on a release film and dried, and cured by irradiation with the active energy radiation to form the present adhesive sheet. A release film may be further laminated as necessary. In this case, it is acceptable that the release film is coated and dried, the adhesive composition [I] is cured by irradiation with the active energy radiation, and the release film may be laminated thereto. Alternatively, it is acceptable that the release film is coated and dried, the release film is laminated, and then the adhesive composition [I] is cured by irradiation with the active energy radiation to form the present adhesive sheet.

Such a solvent is not particularly limited as long as the solvent dissolves the adhesive composition [I]. Examples of the solvent include: ester solvents, such as methyl acetate, ethyl acetate, methyl acetoacetate, and ethyl acetoacetate; ketone solvents, such as acetone, methyl ethyl ketone, and methyl isobutyl ketone; aromatic solvents, such as toluene and xylene; and alcohol solvents, such as methanol, ethanol, and propyl alcohol. These may be used alone, or two or more of these may be used in combination. Among these, ethyl acetate, acetone, methyl ethyl ketone, and toluene are preferable in terms of solubility, drying property, cost, etc., and ethyl acetate is particularly preferably used.

A content of the solvent is preferably not greater than 600 parts by mass, more preferably not greater than 500 parts by mass, further preferably not greater than 400 parts by mass, and particularly preferably not greater than 300 parts by mass relative to 100 parts by mass of the acrylic polymer (A) in terms of drying property. Meanwhile, the content is preferably not less than 1 part by mass, more preferably not less than 50 parts by mass, further preferably not less than 100 parts by mass, and particularly preferably not less than 150 parts by mass.

The coating can be performed by a commonly used method such as roll coating, die coating, gravure coating, comma coating, screen printing, and bar coating, for example.

A content of the solvent in the adhesive composition [I] after drying is preferably not greater than 1 mass %, more preferably not greater than 0.5 mass %, particularly preferably not greater than 0.1 mass %, and most preferably 0 mass %.

The drying temperature is typically 40 to 150° C., more preferably 45 to 140° C., further preferably 50 to 130° C., and particularly preferably 55 to 120° C. The above temperature range can efficiently and relatively safely remove the solvent while inhibiting thermal deformation of the release film.

The drying time is typically 1 to 30 minutes, more preferably 3 to 25 minutes, and further preferably 5 to 20 minutes. The above time range can efficiently and sufficiently remove the solvent.

Examples of the drying method include drying with a drying apparatus or a heat roller, and drying by blowing hot air to the film. Among these, a drying apparatus is preferably used in terms of uniform and easy drying. These may be used alone, or two or more of these may be used in combination.

Examples of the active energy radiation in the irradiation with active energy radiation include: rays, such as far UV, UV, near UV, infrared ray, and visible ray; and ionizing radiations, such as X-ray, α-ray, β-ray, γ-ray, electron beam, proton beam, and neutron beam. Among these, UV is preferable from the viewpoints of reduction in damage of constituent members of an optical apparatus and reaction control. In addition, curing with UV radiation is advantageous in terms of a curing rate, easy availability of the irradiation apparatus, cost, etc.

Examples of a light source of the UV radiation include a high-pressure mercury lamp, an ultrahigh-pressure mercury lamp, a carbon arc lamp, a metal halide lamp, a xenon lamp, a chemical lamp, an electrodeless discharge lamp, and an LED, which emit light with a wavelength region of 150 to 450 nm. Among these, a high-pressure mercury lamp is preferably used.

The radiation is performed under a condition of a radiation dose (integrated light quantity) of active energy radiation of preferably 30 to 3,000 mJ/cm², more preferably 100 to 2,000 mJ/cm², and further preferably 300 to 1,500 mJ/cm² in terms of curing.

After the active energy radiation, heating can be performed as necessary to increase a curing degree.

On at least one surface of the adhesive sheet obtained above, a release film may be provided from the viewpoint of prevention of blocking and prevention of foreign matter adhesion.

As such a release film, known release films can be appropriately used.

As a material of the release film, a film, such as a polyester film, a polyolefin film, a polycarbonate film, a polystyrene film, an acryl film, a triacetylcellulose film, and a fluororesin film, subjected to a releasing treatment by applying a silicone resin; and release paper can be appropriately selected for use, for example.

A thickness of the release film is not particularly limited. Specifically, the thickness is preferably 10 to 250 μm, more preferably 25 to 200 μm, and further preferably 35 to 190 μm from the viewpoints of, for example, processability and handleability.

As necessary, an emboss process or other texturing processes (such as a corn, pyramid shape, or a hemispherical shape) may be performed. For a purpose of improving adhesiveness to each member sheet, the surface may be subjected to surface treatments such as a corona treatment, a plasma treatment, or a primer treatment.

The present adhesive sheet can be provided as an adhesive sheet with the release film by laminating the release film onto one surface or both surfaces of the adhesive layer (the present adhesive sheet) composed of the adhesive composition [I].

### <<The Present Laminated Sheet>>

A laminated sheet according to an example of an embodiment of the present disclosure (hereinafter, which may be referred to as “the present laminated sheet”) is a sheet comprising the present adhesive sheet and another layer. In the layers constituting the present laminated sheet, a thickness of the present adhesive sheet preferably accounts for 10 to 90%, more preferably not less than 20% and not greater than 80%, further preferably not less than 30% and not greater than 70%, in a total thickness of the present laminated sheet.

The present laminated sheet is preferably: a laminate comprising a member sheet on at least one surface of the present adhesive sheet; or a laminate comprising the present adhesive sheet on at least one surface of a member sheet.

The present laminated sheet is preferably a laminated sheet having constitution in which a member sheet (hereinafter, which may be also referred to as “the first member sheet”), the present adhesive sheet, and a member sheet other than the above (hereinafter, which may be also referred to as “the second member sheet”) are laminated in this order, for example.

The present laminated sheet can be produced by adhering the present adhesive sheet to the first member sheet and/or the second member sheet. However, the manufacturing method is not limited thereto. The first member sheet and the second member sheet may be the same as or different from each other.

### <Member Sheet>

Examples of the member sheet (encompassing “the first member sheet” and/or “the second member sheet”) constituting the present laminated sheet, that is, the member sheet to adhere to the present adhesive sheet include: a resin sheet containing, as a main component, at least one resin selected from the group consisting of polyester resin, cycloolefin resin, triacetylcellulose resin, polymethyl methacrylate resin, epoxy resin, polyimide resin, aramid resin, and polyurethane resin; or glass such as thin-film glass. Here, the thin-film glass refers to glass having a thickness of the aforementioned member sheet.

Among these, the resin sheet containing a cycloolefin resin as a main component has a tensile strength at 25° C. (ASTM D882) of as low as 40 to 60 MPa with a thickness of 100 μm. A laminated sheet using such a member sheet having a low tensile strength easily cracks in folding, leading to difficulty in solving the cracking in the scope of conventional art.

As the member sheet, conventionally known sheets can be used. Examples thereof include, but are not limited to, the following.
PET film “S100, available from Mitsubishi Chemical Corporation, thickness: 50 μm” (tensile strength: 73 MPa).
PEN film “FS205S, available from TEIJIN LIMITED, thickness: 50 μm” (tensile strength: 193 MPa).
PI film “C_50, available from Kolon Industries, Inc., thickness: 53 μm” (tensile strength: 204 MPa)

The term “main component” refers to a component accounting for the highest mass proportion in the resin components constituting the member sheet. Specifically, the main component accounts for not less than 50 mass %, preferably not less than 55 mass %, and further preferably not less than 60 mass %, in the member sheet or the resin composition forming the member sheet.

Although depending on the constitution of the flexible image display device and the position of the present adhesive sheet, examples of the first member sheet and the second member sheet include a cover lens, a polarizing plate, a retardation film, a barrier film, a touch-sensor film, and a light emitting element.

In particular, the first member sheet preferably has a touch input function with considering the constitution of the image display. When the present laminated sheet has the aforementioned second member sheet, the second member sheet may also have a touch input function.

### (Tensile Strength at 25° C.)

Furthermore, the first member sheet has a tensile strength at 25° C. measured in accordance with ASTM D882 (also referred to as “25° C. tensile strength (ASTM D882)”) of preferably 10 to 900 MPa, more preferably not less than 15 MPa and not greater than 800 MPa, and further preferably not less than 20 MPa and not greater than 700 MPa.

The first member sheet having the 25° C. tensile strength (ASTM D882) within the above range is preferable because the first member sheet hardly cracks even in bending.

When the present laminated sheet has the aforementioned second member sheet, the second member sheet has a tensile strength at 25° C. measured in accordance with ASTM D882 of preferably 10 to 900 MPa, more preferably not less than 15 MPa and not greater than 800 MPa, and further preferably not less than 20 MPa and not greater than 700 MPa.

The second member sheet having the 25° C. tensile strength (ASTM D882) within the above range is preferable because the second member sheet hardly cracks even in bending.

Specifically, both of the first member sheet and the second member sheet preferably have the tensile strength at 25° C. measured in accordance with ASTM D882 of 10 to 900 MPa.

The first member sheet and the second member sheet may be composed of the same material, or may be composed of different materials.

Examples of the member sheet (encompassing the first member sheet and the second member sheet) having high tensile strength include a polyimide film and a polyethylene naphthalate (PEN) film. These films typically have a tensile strength of not greater than 900 MPa. The lower limit is typically 50 MPa.

On the other hand, examples of the member sheet having a rather low tensile strength include a polyethylene terephthalate (PET) film, a triacetylcellulose (TAC) film, and a cycloolefin polymer (COP) film. These films typically have a tensile strength of not less than 10 MPa. The upper limit is typically 200 MPa.

The present laminated sheet can inhibit defects such as cracking by the action of the present adhesive sheet even when the present laminated sheet has such a member sheet composed of the material having a rather low tensile strength.

### <Physical Properties of the Present Laminated Sheet>

The present laminated sheet can have the following physical properties.

### (Adhesive Force)

The present laminated sheet has an adhesive force (peeling angle: 180°, peeling rate: 300 mm/min, temperature: 23° C.) to the member sheet of the present adhesive sheet of preferably 1 to 30 N/cm, more preferably 2 to 20 N/cm, and further preferably 3 to 10 N/cm.

The present laminated sheet has an adhesive force (peeling angle: 180°, peeling rate: 300 mm/min, temperature: 60° C.) to the member sheet of the present adhesive sheet of preferably 0.5 to 30 N/cm, more preferably 1 to 20 N/cm, and further preferably 1.5 to 10 N/cm. Within such a range, a sufficient adhesive force can be exhibited, and the present laminated sheet tends to be preferably used as the adhesive sheet for the flexible image display device.

The adhesive force can be measured under measurement conditions described in Examples described later.

In the present adhesive sheet, it is important to use a bifunctional (meth)acrylate monomer having an alkylene group having not greater than a predetermined length, specifically the di(meth)acrylate (B1) having an alkylene group having 2 to 4 carbon atoms, as the radically polymerizable compound (B) in order to improve the adhesive force to be more excellent. Further, it is important that the acrylic polymer (A) has the structural portion derived from the alkyl (meth)acrylate (a1) having an alkyl group having 5 to 20 carbon atoms.

The bifunctional (meth)acrylate monomer having an alkylene group having not greater than a predetermined length forms a crosslinked structure with the acrylic polymer (A) by a photopolymerization initiator, and in this case, selecting the above (meth)acrylate forms network with a small crosslinked structure.

This network inhibits slipping the polymers with each other when the adhesiveness test and the recovering ability test are performed, and increases the loss shearing elastic modulus G″ and the loss tangent tan δ to furthermore improve the adhesiveness while having flexibility and recovering ability.

In the measurement of the adhesive force, a peeling mode of peeling the present adhesive sheet from the member sheet is preferably interface peeling.

The image display device constituent member used for the image display device, specifically the foldable and flexible image display device is often expensive, and required to be reworkable for peeling without glue residue if laminating failure occurs in the member-laminating step. To prevent scratch on an image display screen etc., a surface-protective film may be further laminated on a surface of a cover window to be used. When an adhesive layer of the surface-protective film is peeled in such a case, this requires preventing so-called “parting” in which the adhesive layer remains on the surface of the cover window. The peeling mode being the interface peeling can yield the adhesive sheet not to contaminate the product and having excellent reworking ability.

An adhesive sheet having excellent flexibility and having a flexible property tends to decrease an aggregation force to easily cause the peeling mode with an applied peeling force to be aggregation breakage. However, use of the bifunctional (meth)acrylate monomer having an alkylene group having not greater than a certain length, specifically the di(meth)acrylate (B1) having an alkylene group having 2 to 4 carbon atoms, as the radically polymerizable compound (B) achieves excellent aggregability of the flexible adhesive sheet.

The peeling mode of the acrylic adhesive can be judged by visually observing an adhered product after the test for measuring the adhesive force to determine presence or absence of glue residue, for example. More specifically, a case where glue residue at a visually observable level is present can be judged as the aggregation breakage.

### (Dynamic Bending Durability)

As for a reliability test of dynamic bending (dynamic bending durability) of the present laminated sheet, a number of bending at which defects of a bending portion (delamination, breakage, buckling, and floating) do not occur is preferably not less than 100,000, and more preferably not less than 200,000. The number of bending is determined with a U-shape bending cycle evaluation with setting of a curvature radius R=1.5 mm, 60 rpm (1 Hz), −20° C.

The dynamic bending durability test can be performed under measurement conditions described in Examples, described later.

### <Thickness of the Present Laminated Sheet>

A thickness of the present laminated sheet is not particularly limited. For example, the present laminated sheet is, as an example, a sheet when used for an image display device. A thickness of the sheet of not less than 0.01 mm yields good handleability, and the thickness of not greater than 1 mm can contribute to thinning of the present laminated sheet.

Therefore, the thickness of the present laminated sheet is preferably not less than 0.01 mm, further preferably not less than 0.03 mm, and particularly preferably not less than 0.05 mm.

Meanwhile, the upper limit is preferably not greater than 1 mm, further preferably not greater than 0.7 mm, and particularly preferably not greater than 0.5 mm.

### <Method for Manufacturing the Present Laminated Sheet>

Next, a method for manufacturing the present laminated sheet will be described.

The following description is an example of the method for manufacturing the present laminated sheet, and the present laminated sheet is not limited to those manufactured by the following manufacturing method.

The present laminated sheet may be manufactured by preparing the adhesive composition [I] as in the method for manufacturing the present adhesive sheet, and applying and curing this adhesive composition [I] on the first member sheet and/or the second member sheet, for example, for forming the adhesive sheet.

In this case, the method for preparing the adhesive composition [I], the coating method, the method for curing the adhesive composition [I], etc., are the same as those in the method for manufacturing the present adhesive sheet.

Alternatively, the present adhesive sheet may be manufactured in advance and laminated to the first member sheet and/or the second member sheet to manufacture the present laminated sheet.

For a purpose of improving the adhesiveness, each of surfaces of the present adhesive sheet, the first member sheet, and the second member sheet may be subjected to surface treatments such as a corona treatment, a plasma treatment, and a primer treatment.

When the present laminated sheet has the constitution in which the member sheet is laminated to only one surface of the present adhesive sheet, a protective film with a laminated release layer can be provided on the other surface of the present adhesive sheet, the member sheet being not laminated to the other surface.

### <<The Present Flexible Image Display Device Member>>

A flexible image display device member according to an example of an embodiment of the present disclosure (hereinafter, which may be referred to as “the present flexible image display device member”) is a flexible image display device member having constitution in which two flexible members are laminated via the present adhesive sheet.

Among constituent elements in the present flexible image display device member, the present adhesive sheet is the same as above.

Elements other than the adhesive sheet will be described hereinafter.

### (Flexible Member)

Examples of the flexible member constituting the present flexible image display device member include: flexible displays, such as an organic electroluminescence (EL) display; and flexible members for a display, such as a cover lens (cover film), a polarizing plate, a polarizer, a retardation film, a barrier film, a viewing-angle compensating film, a luminescence improving film, a contrast improving film, a diffusing film, a semitransparent reflective film, an electrode film, a transparent conductive film, a metal mesh film, and a touch sensor film. Two of any one or two of them may be used in combination. Examples of the combination include: a combination of a flexible display and another flexible member; and a combination of a cover lens and another flexible member.

The flexible member means a bendable member, specifically a repeatedly bendable member. The flexible member is preferably a member fixable in a curved shape with a curvature radius of not less than 25 mm, and more preferably a member durable for repeated bending actions with a curvature radius of not greater than 25 mm, more preferably a curvature radium of less than 3 mm.

In the aforementioned constitution, examples of a main component in the flexible member include a resin sheet and glass.

Examples of a material of such a resin sheet include polyester resin, cycloolefin resin, triacetylcellulose resin, polymethyl methacrylate resin, polyurethane resin, epoxy resin, polyimide resin, and aramid resin. The material may be one resin or two or more resins. Among these, the resin sheet preferably contains, as a main component, at least one resin selected from the group consisting of polyester resin, cycloolefin resin, triacetylcellulose resin, polymethyl methacrylate resin, epoxy resin, polyimide resin, aramid resin, and polyurethane resin.

Here, “the main component” refers to a component accounting for the highest mass proportion in components constituting the flexible member. Specifically, the main component accounts for preferably not less than 50 mass %, further preferably not less than 55 mass %, and particularly preferably not less than 60 mass %, in the resin composition (resin sheet) forming the flexible member.

The flexible member may be composed of thin-film glass.

In the aforementioned constitution, any one of the two flexible members, namely a first flexible member, preferably has a tensile strength at 25° C. measured in accordance with ASTM D882 of 10 to 900 MPa, particularly preferably not less than 15 MPa and not greater than 800 MPa, and further preferably not less than 20 MPa and not greater than 700 MPa.

The one flexible member preferably has a tensile strength at 25° C. (ASTM D882) within the above range because the flexible member hardly cracks even in bending.

The other flexible member, namely a second flexible member, preferably has a tensile strength at 25° C. measured in accordance with ASTM D882 of 10 to 900 MPa, particularly preferably not less than 15 MPa and not greater than 800 MPa, and further preferably not less than 20 MPa and not greater than 700 MPa.

The other flexible member preferably has a tensile strength at 25° C. (ASTM D882) within the above range because the flexible member hardly cracks even in bending.

Examples of the flexible member having a high tensile strength include a polyimide film, a polyester film, and an aramid film. The tensile strength of these films is typically not greater than 900 MPa.

On the other hand, the flexible member sheet having a rather low tensile strength include a triacetylcellulose (TAC) film and a cycloolefin polymer (COP) film. The tensile strength of these films is typically not less than 10 MPa.

The present flexible image display device member even with such a flexible member composed of the material having a rather low tensile strength can inhibit defects such as cracking by the action of the present adhesive sheet.

### <Method for Manufacturing the Present Flexible Image Display Device Member>

A method for manufacturing the present flexible image display device member is not particularly limited. The adhesive composition [I] may be applied on the flexible member to form the adhesive sheet as noted above, or the adhesive sheet may be formed in advance by using the adhesive composition [I] and then laminated to the flexible member.

### <<The Present Flexible Image Display Device>>

A flexible image display device according to an example of an embodiment of the present disclosure (hereinafter, which may be referred to as “the present flexible image display device”) is an image display device in which the present laminated sheet or the present flexible image display device member is integrated. For example, the present flexible image display device having the present laminated sheet can be formed by laminating the present laminated sheet to another image display device constituent member.

The term “flexible image display device” refers to an image display device that leaves no folding trace even with repeated folding, that can quickly recover to the state before folding when releasing the folding, and that can display a strain-free image even in folding.

More specific examples thereof include an image display device composed of a member fixable in a curved shape with a curvature radius of not less than 25 mm, and more preferably a member durable for repeated bending actions with a curvature radius of less than 25 mm, and more preferably a curvature radius of less than 3 mm.

The present laminated sheet has excellent adhesiveness and can prevent delamination and cracking of the laminated sheet, and has good recovering ability. Therefore, it is one feature of the present laminated sheet that the flexible image display device having excellent flexibility can be produced.

### EXAMPLES

Hereinafter, the present disclosure will be more specifically described with Examples, but the present disclosure is not limited to the following Examples as long as it does not depart from the spirit thereof. In Examples, “parts” and “%” mean those on a mass basis.

### <Raw Material>

First, an acrylic polymer and adhesive composition prepared in Examples, Comparative Examples, and Reference Example, and a detail of an adhesive composition will be described in detail.

### <Acrylic Polymer>

Acrylic Polymers (1) to (3) were prepared with copolymerization component formulations as shown in Table 1.

TABLE 1

| | | | | | | | Glass transition | Glass transition |
|---|---|---|---|---|---|---|---|---|
| Acrylic | Copolymerization components | | | | | Weight-average | temperature | temperature |
| polymer | n-OA | 2EHA | 2HEA | 4HBA | NVP | molecular weight | (Tanδ) | (Theoretical) |
| (A) | (parts) | (parts) | (parts) | (parts) | (parts) | (Mw) | (° C.) | (° C.) |
| (1) | 80 | — | 20 | — | — | 740,000 | −30.5 | −57 |
| (2) | 80 | — | — | 20 | — | 770,000 | −38.1 | −60 |
| (3) | — | 80 | 15 | — | 5 | 960,000 | −25.0 | −59 |

n-OA: n-Octyl acrylate
2EHA: 2-Ethylhexyl acrylate
2HEA: 2-Hydroxyethyl acrylate
4HBA: 4-Hydroxybutyl acrylate
NVP: N-vinylpyrrolidone

### <Radically Polymerizable Compound>

The following compounds were prepared as radically polymerizable compounds.
(B1-1): 1,4-Butanediol diacrylate (BDDA)
(B′-1): 1,10-Decanediol diacrylate (DDDA)

### <Photopolymerization Initiator (C)>

Esacure TZT (available from IGM, mixture of 4-methylbenzophenone and 2,4,6-trimethylbenzophenone (hydrogen abstraction type))

### Examples 1 to 3, Comparative Examples 1 to 3, and Reference Example 1

The acrylic polymer, the radically polymerizable compound, the photopolymerization initiator, and ethyl acetate as a solvent were uniformly mixed in a blending formulation as shown in Table 2 to obtain an adhesive composition solution (solid content concentration: 33%).

TABLE 2

| | Acrylic polymer (A) | | | Radically polymerizable compound (B) | | Photopolymerization | integrated light | |
|---|---|---|---|---|---|---|---|---|
| | (1) | (2) | (3) | B1-1 | B′-1 | initiator | quantity | Thickness |
| | (parts) | (parts) | (parts) | (parts) | (parts) | (parts) | (mJ/cm²) | (μm) |
| Example 1 | 100 | — | — | 1 | — | 3 | 600 | 50 |
| Example 2 | — | 100 | — | 1 | — | 3 | 400 | 50 |
| Example 3 | — | — | 100 | 1 | — | 3 | 600 | 50 |
| Comparative Example 1 | 100 | — | — | — | — | 3 | 1500 | 50 |
| Comparative Example 2 | — | 100 | — | — | — | 3 | 600 | 50 |
| Comparative Example 3 | — | — | 100 | — | — | 3 | 2000 | 50 |
| Reference Example 1 | 100 | — | — | — | 1 | 3 | 600 | 50 |

The adhesive composition solution was applied on a release film (available from Mitsubishi Chemical Corporation, silicone-release treated polyester film, thickness: 100 μm) so that a thickness after drying was as described in Table 2. After application, the coating was placed in a drying apparatus heated to a temperature of 90° C. and retained for 7 minutes to evaporate the solvent contained in the adhesive composition to dryness.

Furthermore, on a surface of the solvent-dried adhesive composition, a release film (available from Mitsubishi Chemical Corporation, silicone-release treated polyester film, thickness: 75 μm) was laminated to form a laminate. The adhesive composition was irradiated with UV through the release film by using a high-pressure mercury lamp (see Table 2 for each irradiation dose) to obtain an adhesive sheet laminate (an adhesive sheet with a release film).

The obtained adhesive sheet laminates were subjected to the following evaluation.

### <Gel Fraction>

The release film was removed from each of the adhesive sheet laminates produced in Examples, Comparative Examples, and Reference Example, and a plurality of the adhesive sheets was laminated to form a laminate with 1.0 mm in thickness. Then, the laminate was punched to a cylinder with 8 mm in diameter to form a sample, and this sample was wrapped with a 200-mesh SUS metal net, and immersed in ethyl acetate adjusted to 23° C. for 72 hours. Thereafter, the sample was dried at 75° C. for 4.5 hours, masses of the adhesive before and after the immersion in ethyl acetate were each measured, and a difference between the masses was regarded as a mass of an insoluble adhesive remained in the metal net. A mass percentage of the insoluble adhesive remained in the metal net relative to the mass of the adhesive before the immersion in ethyl acetate was calculated as a gel fraction (%).

### <Adhesive Force>

One of the release films was removed from each of the adhesive sheet laminates produced in Examples, Comparative Examples, and Reference Example, and on the adhesive surface of the adhesive sheet, a polyethylene terephthalate film (DIAFOIL “S100” available from Mitsubishi Chemical Corporation and having a thickness of 50 μm) was rolling-laminated as a lining film with a hand roller. This laminate was cut to a strip shape with 10 mm in width×150 mm in length, the remaining release film was peeled, and the exposed adhesive surface was rolling-laminated by using a hand roller onto a transparent polyimide film (main component: transparent polyimide, “C_50” available from Kolon Industries, Inc., hereinafter referred to as “CPI film”) laminated onto a stainless steel plate in advance to produce a laminated sheet composed of the CPI film/the adhesive sheet/the lining film. This laminated sheet was left to stand under a room temperature (23° C.) environment for 24 hours to be aged, and a sample for adhesive force measurement was produced.

Under an environment at 23° C. or 60° C., the lining film was peeled while tensing with an angle of 180° formed with the CPI film at a peeling rate of 300 mm/min, and a tensile strength was measured with a load cell to measure a 180°-peeling strength (N/10-mm) of the adhesive sheet relative to the CPI film, which was specified as the adhesive force (23° C. or 60° C.).

A peeling mode with which the adhesive sheet produced in Examples was peeled from the CPI film was interface peeling. A case where the peeling mode was aggregation peeling was noted as “*” in Table.

### <Viscoelasticity Measurement>

A dynamic viscoelasticity of the adhesive sheet was measured, and read from this result was a maximum temperature of a loss tangent (tan δ) (glass transition temperature: Tg) and storage shearing elastic moduli (G′) at −40° C., −20° C., 25° C., and 80° C.

### Loss Tangent (Tan δ) and Storage Shearing Elastic Moduli (G′)

The release film was removed from each of the adhesive sheet laminates produced in Examples, Comparative Examples, and Reference Example, and a plurality of the adhesive sheets was laminated to form a laminate with 1.0 mm in thickness.

The obtained laminate of the adhesive sheet (adhesive layer) was punched to a cylinder with 8 mm in diameter (height: 1.0 mm) to form a sample.

Temperature dispersion of dynamic viscoelasticity of the sample was measured by using a viscoelasticity measuring apparatus (trade name: “DHR 2” available from T.A. Instruments) under the following measurement conditions.

From the obtained temperature dispersion data of dynamic viscoelasticity, a peak temperature of the loss tangent (tan δ) (glass transition temperature (Tg)), the storage shearing elastic modulus at −40° C. G′ (−40° C.), the storage shearing elastic modulus at −20° C. G′ (−20° C.), the storage shearing elastic modulus at 25° C. G′ (25° C.), and the storage shearing elastic modulus at 80° C. G′ (80° C.) were read.

### (Measurement Conditions)

Measurement tool: Φ 8 mm parallel plate
Strain: 0.1%
Frequency: 1 Hz
Measurement temperature: −60 to 100° C.
Temperature raising rate: 5° C./min

### <Recovering Ability>

The release film was removed from each of the adhesive sheet laminates produced in Examples, Comparative Examples, and Reference Example, and a plurality of the adhesive sheets was laminated to form a laminate with 1.0 mm in thickness.

The obtained laminate of the adhesive sheet (adhesive layer) was punched to a cylinder with 8 mm in diameter (height: 1.0 mm) to form a sample.

A recovering rate of the sample was measured and evaluated by using a viscoelasticity measuring apparatus (trade name: “DHR 2” available from T.A. Instruments) under the following measurement conditions.

That is, shearing strain corresponding to a seven-fold thickness was applied at 25° C. with keeping for 10 minutes, and then a remained strain value 10 minutes after the stress was removed was read to measure the recovering ability.

The recovering ability can be determined with the following formula.

Recovering ability (%)=[(700−Remained strain value)/700]×100

Table 3 shows the results obtained by the above measurements and evaluations.

TABLE 3

| | | | | | | | | | Recovering |
|---|---|---|---|---|---|---|---|---|---|
| | Gel | Adhessive force vs. CPI | | Flexibility | | | | | ability |
| | fraction | 23° C. | 60° C. | Tg (Tanδ) | G′ (−40° C.) | G′ (−20° C.) | G′ (25° C.) | G′ (80° C.) | (after 10 min.) |
| | (%) | (N/cm) | (N/cm) | (° C.) | (kPa) | (kPa) | (kPa) | (kPa) | (%) |
| Example 1 | 57 | 9.6 | 2.4 | −31.2 | 7344 | 172 | 18 | 6 | 77 |
| Example 2 | 71 | 3.7 | 1.8 | −39.9 | 1313 | 103 | 14 | 6 | 20 |
| Example 3 | 57 | 10.4 | 3.6 | −25.0 | 34408 | 502 | 38 | 27 | 68 |
| Comparative Example 1 | 51 | 6.6 | 2.3 | −30.5 | 11874 | 248 | 18 | 2 | 60 |
| Comparative Example 2 | 64 | 2.8 | 0.9 | −38.2 | 1001 | 86 | 11 | 5 | 90 |
| Comparative Example 3 | 51 | * | * | −23.8 | 55632 | 725 | 38 | 9 | 51 |
| Reference Example 1 | 70 | 4.3 | 1.3 | −31.9 | 8920 | 197 | 23 | 9 | 82 |

From the above evaluation results, in Examples, the adhesive sheet having a low storage shearing elastic modulus at low temperature and in which the acrylic polymer (A) contains the bifunctional (meth)acrylate monomer having a relatively long-chain alkyl group as the adhesive composition has furthermore excellent adhesiveness.

This is because the bifunctional (meth)acrylate monomer bonds the side chains of the acrylic polymer (A) to each other to inhibit slipping of the polymers each other, resulting in increase in the loss shearing elastic modulus G″. It is presumed that use of the crosslinker having a relatively long chain reduces the network structure with the crosslinking, which furthermore inhibits slipping of the polymers each other to exhibit high adhesiveness.

Therefore, the flexible image display device using the present adhesive sheet is found to have the recovering ability and flexibility, and excellent adhesiveness to inhibit delamination.

Specifically, Comparative Example 1 does not contain the bifunctional (meth)acrylate monomer having a relatively short-chain alkylene group, and in contrast, Example 1 contains such a bifunctional (meth)acrylate monomer, and the adhesive force in Example 1 is higher than that in Comparative Example 1. Similarly, the adhesive force in Example 2 is higher than that in Comparative Example 2. It is found from these results that the adhesive sheet according to Example has recovering ability, and excellent adhesiveness, and the flexible image display device using the adhesive sheet according to Example has recovering ability and flexibility, and excellent adhesiveness.

Example 3 contains the bifunctional (meth)acrylate monomer having a relatively short-chain alkylene group, and in contrast, Comparative Example 3 does not contain such a (meth)acrylate monomer. Thus, the adhesive sheet of Comparative Example 3 has a high storage shearing elastic modulus, specifically a storage shearing elastic modulus at low temperature. Therefore, such an adhesive sheet cannot solve the problems such that the delamination and the folding trace remains in folding operation when used for laminating the flexible image display device constituent member.

In measuring the adhesive force in Comparative Example 3, the adhesive sheet and the CPI film cannot be peeled with the interface to cause aggregation breakage of the adhesive sheet, and thus an accurate adhesive force relative to the CPI interface cannot be measured. Accordingly, Examples in which the peeling mode is the interface peeling are found to exhibit improved reworking ability.

Reference Example 1 contains the bifunctional (meth)acrylate monomer having a relatively long-chain alkylene group for the acrylic polymer (A) as the adhesive composition, and thereby the adhesive sheet has recovering ability but low adhesiveness compared with Example.

The specific embodiments of the present disclosure have been demonstrated in the above Examples, but the above Examples are merely examples and should not be limitedly interpreted. Various modifications obvious to a person skilled in the art are intended to be included within the scope of the present disclosure.

### INDUSTRIAL APPLICABILITY

The adhesive sheet of the present disclosure has good flexibility and recovering ability, and excellent adhesiveness. Therefore, the adhesive sheet is useful as an adhesive sheet for obtaining various flexible image display devices such as bendable, foldable, rollable, and stretchable devices, and specifically preferable for an adhesive sheet for the foldable image display device that causes repeated folding.

1. An adhesive sheet having a storage shearing elastic modulus at −20° C. [G′(−20° C.)] of not greater than 700 kPa, wherein
the adhesive sheet is formed from an adhesive composition [I] comprising an acrylic polymer (A) and a radically polymerizable compound (B),
the acrylic polymer (A) comprises: a structural portion derived from an alkyl (meth)acrylate (a1) with an alkyl group having 5 to 20 carbon atoms; and a structural portion derived from a hydroxy-group-containing (meth)acrylate (a2), and
the radically polymerizable compound (B) comprises a di(meth)acrylate (B1) having an alkylene group having 2 to 4 carbon atoms.

2. The adhesive sheet according to claim 1, wherein the storage shearing elastic modulus at −20° C. [G′(−20° C.)] is not greater than 500 kPa.

3. The adhesive sheet according to claim 1, wherein the alkyl (meth)acrylate (a1) is a linear alkyl (meth)acrylate.

4. The adhesive sheet according to claim 1, wherein the acrylic polymer (A) has a weight-average molecular weight of 600,000 to 1,500,000.

5. The adhesive sheet according to claim 1, wherein the acrylic polymer (A) has a glass transition temperature (Tg) of not lower than −50° C. and not higher than −10° C., the Tg being obtained by a dynamic viscoelasticity measurement with a shearing mode at a frequency of 1 Hz and being defined by a maximum point of a loss tangent (tan δ).

6. The adhesive sheet according to claim 1, wherein the acrylic polymer (A) has a glass transition temperature (Tg) of not lower than −50° C. and lower than −25° C., the Tg being obtained by a dynamic viscoelasticity measurement with a shearing mode at a frequency of 1 Hz and being defined by a maximum point of a loss tangent (tan δ).

7. The adhesive sheet according to claim 1, wherein the di(meth)acrylate (B1) is a di(meth)acrylate having a linear alkylene group.

8. The adhesive sheet according to claim 1, wherein the radically polymerizable compound (B) is contained by 0.1 to 10 parts by mass relative to 100 parts by mass of the acrylic polymer (A).

9. The adhesive sheet according to claim 1, wherein the adhesive sheet has a gel fraction of 30 to 95 mass %.

10. The adhesive sheet according to claim 1, wherein the adhesive sheet has a gel fraction of 30 to 65 mass %.

11. The adhesive sheet according to claim 1, wherein the adhesive sheet is used for laminating a constituent member of a flexible image display device.

12. A flexible image display device, comprising the adhesive sheet according to claim 1.
